(19) United States
(12) Patent Application Publication
(10) Pub. No.: US 2014/0184254 A1
(43) Pub. Date: Jul. 3, 2014

(54) DEBUG CARD

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: BO TIAN, Shenzhen (CN); KANG WU, Shenzhen (CN)

(73) Assignees: HONG FU JIN PRECISION INDUSTRY (ShenZhen) Co., LTD, Shenzhen (CN); HON HAI PRECISION INDUSTRY CO., LTD., New Taipei (TW)

(21) Appl. No.: 14/059,465

(22) Filed: Oct. 22, 2013

(30) Foreign Application Priority Data
Dec. 28, 2012 (CN) 2012105825694

(51) Int. Cl. G01R 31/28

(52) U.S. Cl. CPC G01R 31/28
USPC 324/750.3

(57) ABSTRACT

A debug card includes a connector, a control chip, a pin switching unit, and a control module. The connector is used to connect to a debug signal output port of an electronic device. The connector includes a number of pins. The control chip includes a number of control pins. The pin switching unit is connected between the pins of the connector and the control pin of the control chip. The control module is connected to the pin switching unit, and controls the pin switching unit to establish a first connection relationship between the pins of the connector and the control pins of the control chip by a first connection mode or establish a second connection relationship between the pins of the connector and the control pins of the control chip by a second connection modes.

### BACKGROUND

1. Technical Field

The present disclosure relates to cards, particularly, to a debug card.

2. Description of Related Art

Usually, in order to guarantee the quality of electronic devices, such as, computers, servers, mobile phones, there is a need to debug the electronic device by using a debug card before the electronic device leaves the factory. A common debug card includes a connector, a control chip, and a display unit. The connector is used to connect to a debug signal output port of the electronic device to be debugged and receives the debug signal output by the electronic device. The control chip controls the display unit to display corresponding information according to the received debug signal. FIG. 4 illustrates a connector 10′ of the common debug card, the connector 10′ includes eight pins P1-P8 located on two sides of the connector 10′, namely, a left side of the connector 10′ includes pins P1, P3, P5, and P7, and a right side of the connector 10′ includes pins P2, P4, P6, and P8. Correspondingly, the debug signal output port of the electronic device also includes eight pins located on two sides, and each pin of the debug signal output port is used to connect to one corresponding pin of the connector 10′. However, for different electronic devices, the arrangement of the eight pins of the debug signal output ports are different, therefore, different debug cards need to be prepare for different electronic devices.

Therefore, a debug card to overcome the described limitations is needed.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a block diagram of a debug card in accordance with an exemplary embodiment.

FIG. 2 is a structural diagram of a debug card in accordance with an exemplary embodiment.

FIG. 3 is a schematic diagram of a switch module of a debug card in accordance with an exemplary embodiment.

FIG. 4 is a schematic diagram of a debug card of a related art.

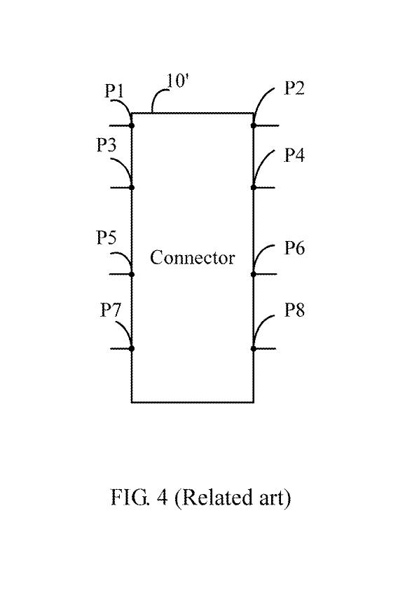

### DETAILED DESCRIPTION

Embodiments of the present disclosure will be described with reference to the accompanying drawings. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

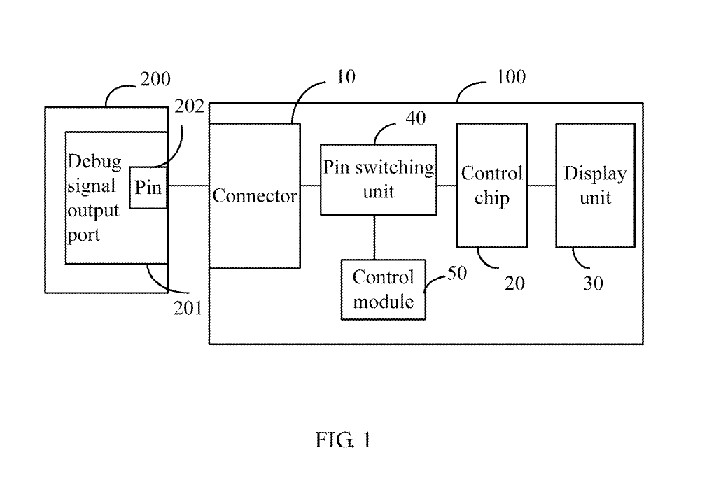

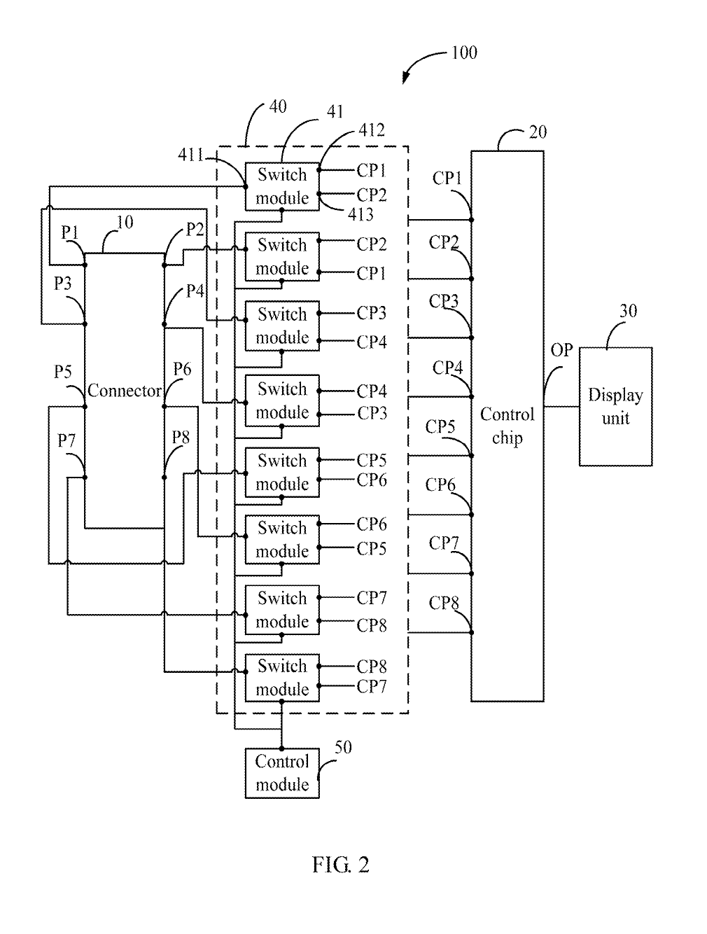

FIGS. 1 and 2 show that a debug card 100 includes a connector 10, a control chip 20, a display unit 30, a pin switching unit 40, and a control module 50. The debug card 100 is used to test/debug an electronic device 200. The electronic device 200 includes a debug signal output port 201 with a number of pins 202. The debug signal output port 201 outputs debug signals when the electronic device 200 is on the process of being debugged.

The connector 10 is used to connect to the debug signal output port 201 of the electronic device 200. As shown in FIG. 2, the connector 10 includes a number of pins P1-P8 which are divided into a first group of pins P1, P3, P5, and P7 and a second group of pins P2, P4, P6, and P8. The first group of pins P1 , P3, P5, and P7 are located on a left side of the connector 10, and a second group of pins P2, P4, P6, and P8 are located on a right side of the connector 10. The pins P1-P8 are connected to the pins 202 of the debug signal output port 201 when the connector 10 connects to the debug signal output port 201.

The control chip 20 includes a number of control pins C1-C8 and an output pin OP. The output pin OP is connected to the display unit 30. The control pins C1-C8 are connected to the pins P1-P8 of the connector 10 and then connects to the pins 202 of the debug signal output port 201 and receives the debug signal output by the debug signal output port 201 via the connector 10. The control chip 20 controls the display unit 30 to display corresponding information according to the debug signal received by the control pins C1-C8. In the embodiment, the display unit 30 can be a liquid crystal display, an electrophoretic display, or a seven segment digital tube, for example.

The pin switching unit 40 is connected between the pins P1-P8 of the connector 10 and the control pins C1-C8 of the control chip 20.

The control module 50 is connected to the pin switching unit 40, and is used to control the pin switching unit 40 to establish a first connection relationship between the pins P1-P8 of the connector 10 and the control pins C1 -C8 of the control chip 20 by a first connection mode. The control module 50 is also used to control the pin switching unit 40 to establish a second connection relationship between the pins P1-P8 of the connector 10 and the control pins C1-C8 of the control chip 20 by a second connection mode, in response to user operation.

In the embodiment, when the pin switching unit 40 establishes the first connection relationship by the first connection mode, the pin switching unit 40 respectively connects the pins P1-P8 of the connector 10 and the control pins C1-C8 of the control chip 20. Thus establishing the first connection relationship.

When the pin switching unit 40 establishes the second connection relationship by the second connection mode, the pin switching unit 40 respectively connects the pins P2, P1, P4, P3, P6, P5, P8, and P7 to the pins C1-C8 of the control pin 20 to establish the second connection relationship.

Therefore, when definitions of the pins 202 of the debug signal output port 20 respectively correspond to definitions of the pins P1-P8 of the connector 10, such as, the definitions of the pins 202 of the debug signal output port 20 respectively are a power pin, a ground pin, a first data pin, a second data pin, etc., and the definitions of the pins P1-P8 of the connector 10 respectively are the power pin, the ground pin, the first data pin, the second data pin, etc., the control module 50 controls the pin switching unit 40 to establish the first connection relationship. When the definitions of the pins 202 of the debug signal output port 201 are different from the definitions of the pins P1-P8 of the connector 10, such as, the definitions of the pins of the debug signal output port 201 located on left side correspond to the definitions of the pins of the connector located on right side, and the definitions of the pins of the debug signal output port 201 located on the right side correspond to the definitions of the pins of the connector located on the left side. The control module 50 then controls the pin switching unit 40 to establish the second connection relationship between the pins P1-P8 and the control pins C1-C8 by the second connection mode. Therefore, if the definitions of the pins 202 of the debug signal output port 20 are different from the definitions of the pins P1-P8 of the connector 10, the control pins C1-C8 connects the corresponding pins 202 of the debug signal output port 201 as well.

FIG. 2 shows that the pin switching unit 40 includes a number of switch modules 41. The number of the switch modules 41 is equal to the number of the pins P1-P8 of the connector 10 and the number of the pins 202 of the debug signal output port 201. In the embodiment, the number of the switch modules 41, the number of the pins P1-P8 of the connector 10, and the number of the pins 202 of the debug signal output port 201 are all eight. Obviously, in another embodiment, the number of the pins P1-P8 of the connector 10 and the switch modules 41 can be any suitable even value, such as six, twelve.

Each switch module 41 includes an input terminal 411, a first output terminal 412, and a second output terminal 413. The input terminals 411 of the switch modules 41 are connected to the pins P1-P8 of the connector 10 one by one. The first output terminals 412 of the switch modules 41 are connected to the control pins C1-C8 of the control chip 20 one by one according to a first sequence. The second output terminals 413 of the switch modules 41 are connected to the control pins C1-C8 of the control chip 20 one by one according to a second sequence.

In the embodiment, the first sequence is that the first output terminals 412 of the switch modules 41 that are respectively connected to the pins P1-P8 are respectively connected to the control pins C1-C8 of the control chip 20. Namely, the first output terminal 412 of the switch module 41 connected to the pin P1 of the connector 10 is connected to the control pin C1, the first output terminal 412 of the switch module 41 connected to the pin P2 of the connector 10 is connected to the control pin C2, the first output terminal 412 of the switch module 41 connected to the pin P3 of the connector 10 is connected to the control pin C3, and etc.

The second sequence is that the second output terminals 413 of the switch modules 41 that are respectively connected to the pins P1-P8 are respectively connected to the control pins C2`C1`C4`C3`C6`C5`C8`C7 of the control chip 20. Namely, the second output terminal 413 of the switch module 41 connected to the pin P1 of the connector 10 is connected to the control pin C2, the second output terminal 413 of the switch module 41 connected to the pin P2 of the connector 10 is connected to the control pin C1, the second output terminal 41 of the switch module 41 connected to the pin P3 of the connector 10 is connected to the control pin C4, and etc.

The control module 50 is connected to all of the switch modules 41, and is used to control each switch module 41 to connect the input terminal 411 with the first output terminal 412 or with the second output terminal 413.

When the definitions of the pins 202 of the debug signal output port 201 respectively correspond to the connector 10, the control module 50 controls each switch module 41 to connect the input terminal 411 with the first output terminal 412. Therefore, when the input terminals 411 of the switch modules 41 are respectively connected to the first output terminals 412, the pins P1-P8 of the connector 10 are respectively connected to the control pins C1-C8 of the control chip 20 via the switch modules 41. Thus to establish the first connection relationship between the pins P1-P8 of the connector 10 and the control pins C1-C8 of the control chip 20.

When the definition of the pins 202 of the debug signal output port 201 do not correspond to the pins P1-P8 of the connector 10; namely, the definitions of the pins located on two sides of the debug signal output port 201 are opposite to the definitions of the pins P1-P8 located on the two sides of the connector 10. The control module 50 controls each switch module 41 to connect the input terminal 411 with the second output terminal 413. When the input terminals 411 of the switch modules 41 are respectively connected to the second output terminals 413, the pins P1-P8 of the connector 10 are respectively connected to the control pins C2`C1`C4`C3`C6`C5`C8`C7 of the control chip 20 via the switch modules 41. Thus the second connection relationship between the pins P1-P8 of the connector 10 and the control pins C1-C8 of the control chip 20 is established The control pins C1-C8 connect to the corresponding pins 202 of the debug signal output port 201 and can receive the debug signal from the debug signal output port 201. Then the control chip 20 controls the display unit 30 to display corresponding information according to the debug signal received from the debug signal output port 201.

At this time, the control pins C1-C8 of the control chip 20 are respectively connected to the pins P2, P1, P4, P3, P6, P5, P8, and P7 of the connector 10. Therefore, the pins of the connector 10 on the left side and the right side are switched and then are respectively connected to the control pins C1-C8. The control pins C1-C8 remain connected to the corresponding pins 202 of the debug signal output port 201 and can receive the debug signal from the debug signal output port 201. Then the control chip 20 controls the display unit 30 to display corresponding information according to the debug signal received from the debug signal output port 201.

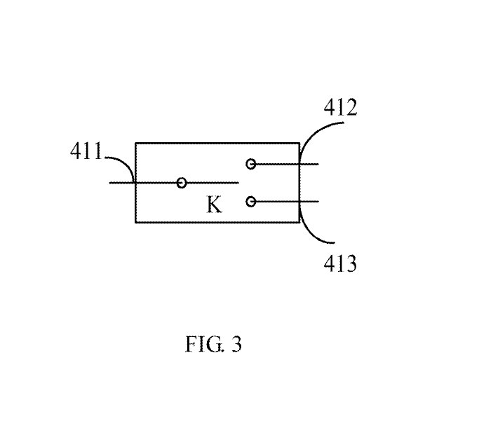

FIG. 3 shows that in the illustrated embodiment, each switch module 41 is a single pole double throw (SPDT) switch K. A common terminal of the SPDT switch K constitutes the input terminal 411 of the switch module 41. Two contact terminals of the SPDT switch K constitute the first output terminal 412 and the second output terminal 413 of the switch module 41. The common terminal of the SPDT switch K can be controlled to connect to one of the contact terminals, thus making the input terminal 411 to connect to the first output terminal 412 or the second output terminal 413. In other embodiment, the switch module 41 can be a jump line hat and any other suitable structure. In further another embodiment, the pin switching unit 40 can be a multi-way switch.

In the embodiment, the control module 50 can be a push-button, which produces a switch signal to control the switch module 41 to switch the connection between the input terminal 411 and the first output terminal 412, the second output terminal 413, in response to a press of the user. In another embodiment, the control module 50 can be a single chip, or a processor, for example. The control module 50 produces the switch signal in response to a corresponding command input by the user.

Therefore, the debug card 100 of the present invention can be used to debug different kinds of electronic device.

In the illustrated embodiment, the control chip 20 can be a single chip, a digital processor, or central processing unit, for example.

In the embodiment, the electronic device 200 can be a desktop computer, a portable computer, a tablet computer, a server, and other computers, and also can be a mobile phone, a digital camera, a digital photo frame, and any devices needed to be debugged.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A debug card for debugging an electronic device, comprising:
a connector configured to connect to a debug signal output port of the electronic device; wherein, the connector comprises a plurality of pins divided to a first group of pins and a second group of pins, the first group of pins are located on a left side of the connector, and a second group of pins are located on a right side of the connector;
a control chip comprising a plurality of control pins;
a pin switching unit connected between the pins of the connector and the control pins of the control chip; and
a control module connected to the pin switching unit, and configured to control the pin switching unit to establish a first connection relationship between the pins of the connector and the control pins of the control chip according to a first connection mode, or a second connection relationship between the pins of the connector and the control pins of the control chip according to a second connection mode, in response to user operation.

2. The debug card according to claim 2, wherein the connector comprises eight pins, and the control chip comprises eight control pins; a first pin, a third pin, a fifth pin, and a seventh pin of the connector constitute the first group of pins and are located on the left side of the connector, a second pin, a fourth pin, a sixth pin, and a eighth pin of the connector constitute the second group of pins and are located on the right side of the connector; the first connection mode is that the pin switching unit respectively connects the control pins of the control chip from a first control pin to a eighth control pin with the pins of the connector from the first pin to the eighth pin; the second connection mode is that the pin switching unit respectively connects the second pin, the first pin, the fourth pin, the third pin, the sixth pin, the fifth pin, the eighth pin, and the seventh pin of the connector with the control pins of the control chip from the first control pin to the eighth control pin.

3. The debug card according to claim 2, wherein the pin switching unit comprises a plurality of switch modules, each switch module comprises an input terminal, a first output terminal, and a second output terminal; the input terminals of the switch modules are connected to the pins of the connector from the first pin to the eighth pin one by one, the first output terminals are connected to the control pins of the control chip one by one according to a first sequence, and the second output terminals of the switch module are connected to the control pins of the control chip one by one according to a second sequence.

4. The debug card according to claim 3, wherein the first sequence is defined as: the first output terminals of the switch modules that are respectively connected to the pins of the connector from the first pin to the eighth pin are respectively connected to the control pins of the control chip from the first control pin to the eighth pin; and the second sequence is defined as: the second output terminals of the switch modules that are respectively connected to the pins of the connector from the first pin to the eighth pin are respectively connected to a second control pin, the first control pin, a fourth control pin, a third control pin, a sixth control pin, a fifth control pin, the eighth control pin, and a seventh control pin of the control chip.

5. The debug card according to claim 4, wherein the control module is connected to all of the switch modules, and is configured to control each switch module to connect the input terminal with the first output terminal or to connect the input terminal with the second output terminal, in responses to user operation.

6. The debug card according to claim 5, wherein when the debug signal output port of the electronic device matches the connector, the control module controls the each switch module to connect the input terminal with the first output terminal, the pins of the connector from the first pin to the eighth pin are respectively connected to the control pins of the control chip from the first control pin to the second control pin via the switch modules, thus to establish the first connection relationship between the pins of the connector and the control pins of the control chip; when the debug signal output port of the electronic device does not matches the connector, the control module controls each switch module to connect the input terminal with the second output terminal, the pins of the connector from the first pin to the eighth pin are respectively connected to the second control pin, the first control pin, the fourth control pin, the third control pin, the sixth control pin, the fifth control pin, the eighth control pin, and the seventh control pin of the control chip via the switch modules, thus to establish the second connection relationship between the pins of the connector and the control pins of the control chip.

7. The debug card according to claim 6, wherein the switch module is a single pole double throw (SPDT) switch, a common terminal of the SPDT switch K constitutes the input terminal of the switch module, two contact terminals of the SPDT switch constitute the first output terminal and the second output terminal of the switch module.

8. The debug card according to claim 7, wherein the control module is a push-button, which produces a switch signal to control the switch module to switch the connection between the input terminal and the first output terminal, the second output terminal, in response to a press of the user.

9. The debug card according to claim 1, further comprising a display unit, wherein the control chip further comprises an output port connected to the display unit, the control chip is further configured to control the display unit to display corresponding information via the output port according to a debug signal received from the debug signal output port.
